(19) United States
(12) Patent Application Publication
(10) Pub. No.: US 2013/0130510 A1
(43) Pub. Date: May 23, 2013

(54) Semiconductor Substrate Transfer/Processing-tunnel -arrangement, with Successive Semiconductor Substrate - Sections

(71) Applicant: Edward Bok, Lelystad (NL)

(72) Inventor: Edward Bok, Lelystad (NL)

(21) Appl. No.: 13/698,488

(22) PCT Filed: May 18, 2010
(86) PCT No.: PCT/NL2010/000082

§ 371 Date: Jan. 31, 2013

(51) Int. Cl. H01L 21/02

(52) U.S. Cl. CPC H01L 21/02104
USPC 438/758; 118/500

(57) ABSTRACT

Semiconductor substrate transfer treatment/processing tunnel-arrangement, containing such means, that thereby also during the uninterrupted operation thereof the uninterruptedly taking place of the establishing of a (sub) micrometer high layer of semiconductor substances with an optimum uniform height thereof upon the successive semiconductor substrate-sections, uninterruptedly displacing therethrough and such by means of through a strip-shaped supply-section of the uppertunnelclock in its central semiconductor section the uninterruptedly taking place of a supply of the combination of fluidic support-medium and parts of a semiconductor substance in a solid- or fluidic form thereof and in the thereupon following strip-shaped semiconductor treatment/processing section underneath a vibrating transducer-arrangement, located in a transducer-compartment of this block, the also by means of the in addition developed heat of this vibrating transducer the taking place of evaporation of this support-medium under an at-least almost uniform deposition of these particles of a semiconductor substance upon these successive semiconductor substrate-sections, displacing underneath, and the discharge of the established vapor through a thereupon following strip-shaped discharge-section in this block.

In this Patent Application a semiconductor substrate transfer/processing tunnel is shown and described, with during its working therein an uninterrupted linear displacement therethrough of successive semiconductor substrate-sections takes place, and whereby locally in the uppertunnelblock the location of at least one strip-shaped transducer, located in a from the outer atmospheric air separated transducer-compartment.

Thereby in this block in front of typically the first transducer the location of a strip-shaped supply-section for the combination of a typically very low-boiling fluidic support-medium and typically nanometer sized particles of a semiconductor substance in a solid and/or fluidic form thereof.

Furthermore, in the upper split-section underneath the transducer by means of the therewith developed heat the uninterruptedly taking place of a gradual evaporation of this fluidic supply-medium under at the end at least near the back-section thereof the establishment of evaporation of at least almost all successively supplied support-medium under at least almost all successively supplied support-medium under at least almost a total deposition of these particles of a semiconductor substance on the successive semiconductor substrate-sections, displacing underneath, with an already established high rate of flatness of the deposited micrometer high layer thereof and such also by means of the thereby maintaining of a typically vibration-condition of the established vapor above these particles and whereby in a following strip-shaped discharge-section of this block the taking place of a discharge of this vapor.

Thereby in addition at least also the following:

1. Through a device above the upper tunnelblock the uninterruptedly taking place of an optimal continuous uniform supply of a specific volume of the combination of the fluidic support-medium and the particles of a semiconductor substance for a period of time.
2. In a device above the uppertunnelblock the following uninterruptedly taking place of an optimal mixing of this combination.
3. An uniform supply of this combination via a large number of medium-supplychannels, located aside and above each other and at least contained within this block in the central semiconductor processing-section of the tunnel-passage, with by a width of typically 200 mm of this central section the application of typically approximately 32 mini medium-supplyblocks in the lower section thereof.
4. The location in the lower wall of these supply-blocks a (sub) micrometer wide connection-groove, with aside thereof located a number of grooves in the lower wall of this uppertunnelblock, extending in a sideward direction of the tunnel-passage, and establishing one uninterrupted medium-supplygroove.
5. During the fabrication of the lowertunnelblock the establishing of an ultra flatness in both longitudinal and transverse direction of its top-wall and such at least at the central semiconductor processing-section of the tunnel-passage.
6. An optimal flatness of both these lower- and upper-wall in combination with an uniform thickness of the during the operation of this tunnel-arrangement through the entrance thereof therein uninterruptedly supplied semiconductor band and/or folio as an at least temporary semiconductor underlayer of the successive semiconductor substrate-sections, displacing therethrough.
7. Typically at least locally the maintaining of a downwardly pressed-upon position of these successive band- and/or folio-sections on the sections of the lowertunnelblock, located underneath the central semiconductor processing-section, during its displacement.
8. The continuous maintaining of an uniform, very low speed of the successive semiconductor substrate-sections, uninterruptedly displacing through the tunnel-arrangement.
9. No unacceptable deformations of these successive substrate-sections in a strip-shaped tunnel-section during the uninterruptedly taking place of an oven-treatment of the applied, only micrometer high layer of a semiconductor substance by means of an electric heating element, located in the lower wall of the uppertunnelblock.
10. The continuously maintaining of a certain ratio between the fluidic support-medium and:
a) these parts of a semiconductor substance in a solid form thereof; or
b) these parts of a semiconductor substance in a fluidic form thereof; or
c) the combination of these parts of a semiconductor substance in a typically solid form thereof and a high-boiling fluidic mixing-fluid.
   11. By means of this strip-shaped transducer continuously at least the accomplishing and maintaining therewith of the following:
a) an uniform division of this combination of fluidic support-medium and parts of a semiconductor substance in a transverse direction of the tunnel-passage; and
b) an uniform displacement of this combination in the direction of displacement of the successive substrate-sections.
   12. An ultra flat lower wall of this transducer in both the longitudinal- or transverse direction thereof by means of at least the following:
a) the low development of heat thereof; and
b) an uniform downward force thereon of the gaseous medium in the transducer-compartment.
   13. By means of the continuously maintaining of a vibrating-condition of this transducer an impossible sticking of parts of this semiconductor substance against the lower wall thereof.
   14. By means of the transducer-compartment, also functioning as a thrust-chamber, at least locally in this tunnel the functioning of this transducer thereby also as a low-frequently pulsating lower wall thereof, with locally the establishing and subsequently shortly maintaining of a mechanically contact-free press-upon condition of the vibrating lower wall thereof on the micrometer high layer of typically parts of a solid substance, established therewith.
   15. By means of this transducer also the continuously taking place therewith of a semiconductor penetration-process of parts of such semiconductor substance in a solid and/or fluidic form thereof into the semiconductor top-layer of these successive semiconductor substrate-sections, displacing underneath thereof, to establish an optimal anchorage of the established layer of these parts within this semiconductor top-layer.
   16. In this tunnel the ideal establishing of only one semiconductor layer of semiconductor substances for the successive semiconductor substrate-sections at the exit thereof to its establishment of semiconductor chips with a single top-layer by means of a separation of these substrate-sections.
   17. At least also by means of this continuously maintaining of an ultra flat condition of the successively established semiconductor layers of in particular solid substances the ideal possibility of establishing a number of semiconductor layers above each other, with electric connections in-between to establish semiconductor chips, a number of semicon layers on top of each other, with electric connections in-between.

By applying two successive strip-shaped transducers in this uppertunnelblock under the first transducer the therewith continuous building-up of a micrometer high layer of a semiconductor substance in a solid form thereof or a nanometer-high layer of a semiconductor substance in a fluidic form thereof, with a thereby established almost flat condition of the upper wall thereof, and by means of the second transducer the taking place of an uninterrupted flatness-process of the established layer to subsequently establish an optimal flatness of such established semiconductor layer.

Thereby such a combination of two successive transducers is extremely simple, with also a very restricted total circumference thereof, as thereby a total length of typically only approximately 70 mm and a width in transverse direction of typically less than 300 mm.

In addition, other constructions of such s transducer-structure are possible, as such transducers are already commonly used in the existing semiconductor installations.

Furthermore, by means of such transducer-arrangement the uninterruptedly taking place of a semiconductor penetration-process of parts of a semiconductor substance in the already applied semiconductor top-layer or the top-stratun of a whether or not metallic folio as a semiconductor bottom-stratum of the successive semiconductor substrate-sections.

By means of the via these large number, typically 32, aside each other located mini medium-supplyblocks, with typically therein only one medium transfer-channel, with a diameter thereof of typically less than 0.1 mm, the minimizing of the uninterrupted supply per second of this combination of fluidic support-medium and parts of a semiconductor substance, in total typically less than 1 mm³ per second, to build-up therewith a nanometer high semiconductor bottom-layer under an sufficient anchorage thereof upon the successive folio-sections as an at least temporary semiconductor under-layer thereof, or the therewith establishing of a (sub) micrometer high layer of a semiconductor substance on such bottom-layer and whereby a very restricted and allowable heating of the top-layer thereof.

Such an anchorage-process of the established nanometer high layer of nanometer sized particles in the semiconductor top-layer of the successive, uninterruptedly displacing semiconductor substrate-section a underneath, with the following taking place of such an oven-treatment of this layer under the inversion thereof into a fluidic condition thereof and the melting of these inverted parts together with the above located part of this layer, resulting in an affixing of these successive parts of this layer with the semiconductor substrate-sections, moving underneath.

The heat-development of such transducer amounts typically only approx. 0.5 cal/cm³/second.

With a transducer-surface of for instance approx. 30 cm², consequently a heat-development thereof of approx. 15 cal/second.

To enable the evaporation of the uninterruptedly supplied fluidic support-medium typically approx. 75 cal/cm³ is required.

As the supply thereof only amounts typically approx. 1 mm³/second, evidently already near the entrance-section of this transducer by means of the relatively high temperature thereof a change of the fluidic medium into vapor takes place.

As a result, the use of fluidic support-medium with such an adapted boiling temperature thereof, that in the following semiconductor processing-section not a boiling thereof takes place.

Also due to the above noted the following:
a) a small required width of such transducer;
b) an optimal cooling of the front-section thereof, if by means of such transducer the taking place of such an insertion-process;
c) the possible application of a relatively high boiling fluidic medium; and
d) by means of the vibrating action thereof always an uninterruptedly taking place of a deposition of the relatively heavy particles of a semiconductor substance in a solid form thereof on the successive substrate-sections, uninterruptedly displacing underneath.

With the existing semiconductor installations, using the combination of semiconductors and -modules, after the in such individual module taking place of an established established semiconductor layer of parts in a solid form thereof at least also the following is required:
a) a following oven-treatment thereof in a separate semiconductor device, with thereafter the typically required taking place of a strip-process for the upper wall thereof to enable the obtaining of a required optimal flatness of the applied semiconductor layer under a thereby required discharge of the removed particles of the semiconductor substance; and
b) after a following cleaning-process of the top-wall, with subsequently typically a required rinsing- and drying-process in typically also separate devices, in addition a required robotic discharge of such wafer toward a storage-establishment.
   Thereby a required floor-surface for such a combination of semiconductor processings at least approx. 150 times larger than that of such semiconductor tunnel-arrangement and a required approx. 15 times longer lasting time, with personal to at least also control the correct robotic supply- and discharge of these wafers toward and from the semiconductor modules and -devices and inspection of these successive semiconductor treatments.

By means of the also possible low vibration-level of such ceramic transducers, typically lower than 132000 vibrations per second, in addition the ideal possible application of such strip-shaped transducer in such transducer-compartment of the lowertunnelblock, with during operation thereof the continuously maintaining of also a vibration of the successive semiconductor substrate-sections, uninterruptedly displacing over such transducer.

Thereby in a favourable construction of such tunnel the location of such transducer at least locally under at least part of the in the uppertunnelblock located strip-shaped transducer.

Thereby also for such transducer every possible size in both the longitudinal- and transverse direction and also any possible construction thereof.

In still another favourable tunnel-construction at least locally in the lowertunnelblock the insertion of a shaft, containing notches, and also typically located in a from the atmospheric air separated compartment, with at least locally the position thereof underneath at least a section of such strip-shaped transducer, located in the uppertunnelblock.

Thereby during the operation of this tunnel the uninterruptedly rotation thereof under a high number, typically approx. 3000, rotations per minute.

On such shaft, within the central treatment-section of this tunnel, the location of a number, typically at least 10, micrometer high notches, whereby such notch, as seen in the direction of its rotation, containing the following profiles thereof:
a) a very small length of the increasing sidewall-section together with following relatively considerable length of the declining section thereof; or
b) a relatively considerable length of the increasing sidewall-section and a successive very small length of the declining section thereof.

Further, that thereby this compartment at the top-wall of this lowertunnelblock contains an in the upward direction displaceable strip-shaped relatively thick thrust wall-section, with around thereof a membrane-section with a small height thereof to enable a successive up- and downwardly displacement therewith of this underneath thereof rotating nockshaft-structure, with a corresponding up- and downwardly displacement of the successive substrate substrate-sections, uninterruptedly displacing on top thereof.

Thereby in this compartment at least a filling with such a fluidic lubricant, that thereby a (sub) micrometer thick layer thereof is located in-between this rotating notch-shaft and this vibrating plate.

In that way during the rotation of such notch-shaft the successively up- and downward displacement of this thrust plate-section and therewith of the successive semiconductor substrate-sections, displacing thereover.

As a result, the accomplishing and subsequently continuous maintaining of the combination of the high-frequently up- and downward displacing of the semiconductor processing-medium and its vibration.

In addition, an optimization of such a semiconductor treatment-process by means of in addition such a transducer in the top-wall of this tunnel and the successive substrate-sections, displacing in-between, with thereby in particular also a possible optimal semiconductor inversion-process of parts of such a demiconductor substance into the semiconductor top-layer thereof.

Thereby in this notchshaft-compartment the maintaining of at least partly the filling thereof with fluidic medium.

Furthermore, typically also at least locally in the lower split-section underneath such successive substrate-sections the maintaining of a micrometer high film of a very thin fluidic guidance medium.

By using in addition also such a strip-shaped transducer or rotating notch-shaft in the lowertunnelblock almost immediately behind the strip-shaped medium-supplysection the combination thereof with the upper-transducer, thereby in a favourable semiconductor procedure of this tunnel an uninterruptedly supply taking place of the combination of gaseous support-medium, fluidic support-medium and parts of a semiconductor substance.

Thereby by means of the established vibration of the successive substrate-sections under the usage of this under-transducer or -notch-shaft already immediately after the supply of such combination an optimal taking place of a semiconductor inversion-process with these particles of a semiconductor substance in the semiconductor top-layer of these successive substrate-sections.

In this tunnel in addition by means of at least such a strip-shaped upper-transducer the possible taking place of semiconductor treatment-processes, also the ones, which already commonly are taking place in the existing semiconductor installations under the usage of at least also semiconductor wafers and such in an adapted processing-condition thereof, as for instance a cleaning-, etch-, strip-, rinse- or polishing-process and ion implantation, to accomplish nanometer wide grooves and crevices in the semiconductor top-layer, with the filling of these grooves and crevices with nanometer-sized metallic parts.

Such transducer-arrangement contains typically a number of at-least aside each other located small individual, typically cylindrical transducers, with every possible size, also its height.

Thereby for instance the following arrangements thereof:

1. A number of only in the transverse direction of the tunnel aside each other positioned transducers and whereby a thin strip-shaped part of the lower wall of the transducer-compartment at least also functions as a lower electrode-plate of these transducers.

On top thereof a common strip-shaped upper electrode-plate, that through an electrical junction is connected with an electronic generator and wherein the uninterruptedly taking place of the generation of electrical vibrations and whereby by means of such transducer these electrical vibrations are transversed into mechanical vibrations, with typically an 0.1-1.5 micrometer amplitude thereof;

2. Two, in transverse direction of this tunnel shifted aside each other rows of transducers, with typically a diameter thereof smaller then 25 mm, and such rows also extent over at least the central semiconductor treatment/processing-section thereof.
Thereby also a thin-walled section of the lower wall of this compartment at least functions as a common under-electrodeplate of these transducers, with above a common strip-shaped upper-electrodeplate, also through such electrical junction connected with such electronic generator; and
3. Three rows of shifted aside each other located transducers, being also part of such an transducer-compartment, with typically a diameter of less then 20 mm of such cylindrical transducers and whereby such rows also extent in transverse direction of at least the central semiconductor treatment/processing-section thereof.

In these transducer-arrangements during the assembling of such individual transducers onto such a lower- and upper plate the accomplishing of at least a micrometer small split in-between to prevent an unallowable deformation of such assembly, due to the grow of these transducers as the result of the heat-development therein.

Furthermore, in a favourable alternative build-up of such tunnel at least locally the mounting of an exchangeable rotating notch-shaft in the uppertunnelblock, extending in transverse direction over at least the central semiconductor treatment/processing-section and is also a part of an enclosed strip-shaped notchshaft-compartment.

Thereby typically in addition at least near the lower wall of this compartment the location of a strip-shaped electrical heating-element to function as a vibrating/pulsating arrangement for the strip-shaped thrust wall-section of the uppertunnelblock in combination with such heating thereof, that thereby the uninterruptedly taking place of an at least almost total evaporation of such low-boiling fluidic support-medium.

Such combination of a rotating shaft, containing a series of notches, and an electric heating-element, as an alternative alternative for such a strip-shaped transducer-arrangement in this block.

Furthermore, in alternative medium-supplysystems the uninterruptedly taking place of a supply through such strip-shaped supply-device of the following combinations:
a) low-boiling fluidic support-medium, particles of gaseous support-medium and particles of a semiconductor substance in a solid- and/or fluidic form thereof; and
b) very low-boiling fluidic support-medium and a higher boiling fluidic support-medium in combination with such particles of a semiconductor substance.

Furthermore, at least locally only the application of gaseous support medium and such particles of a semiconductor substance in a solid and/or fluidic form thereof.

Additional favourable features of this section of the semiconductor tunnel-arrangement under at least also the application of such strip-shaped upper- and/or lower vibration-device follow from the description of the Figures, shown underneath.

Furthermore for this tunnel-arrangement the following:
a) therein the possible application of means and methods, as described and shown in the accompanying, at the same time submitted Dutch Patent Applications of the Applicant;
b) the possible application of the semiconductor means and -methods, as are described and shown in this Dutch Patent Application of the Applicant with regard to a semiconductor tunnel-arrangement, in the semiconductor tunnel-arrangements, as described and shown in at least these accompanying Dutch Patent Applications; and
c) the possible use of semiconductor means, -methods and -substances, as already commonly used in the already existing semiconductor installations, wherein the use of semiconductor devices, -modules and -wafers.

The invention shall underneath further be explained by means of a number of a number of applicable examples of this semiconductor tunnel-arrangement.

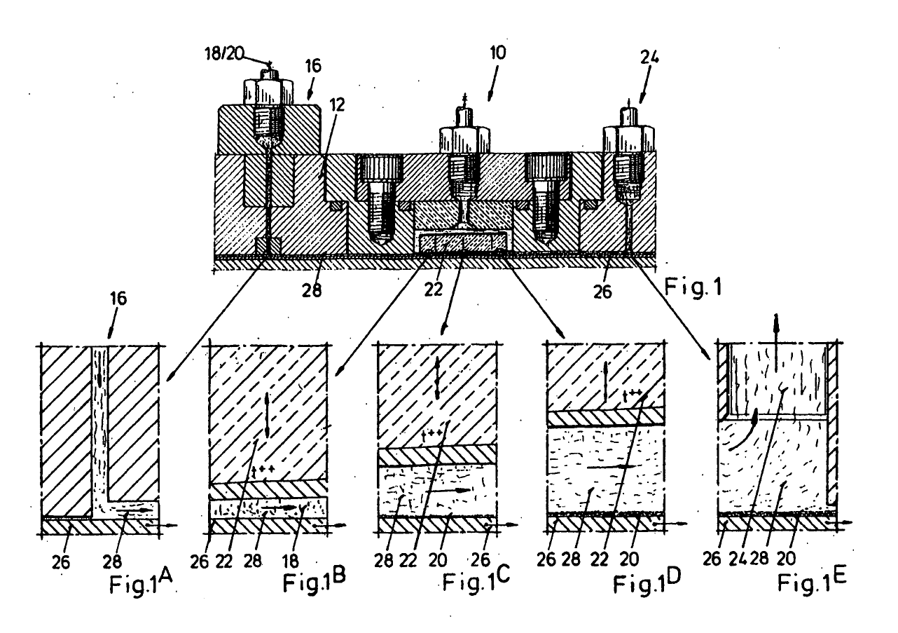

FIG. 1 shows a section of a semiconductor tunnel-arrangement, whereby in the uppertunnelblock the location of a strip-shaped medium supplygroove-arrangement for the uninterrupted supply of the combination of fluidic support-medium and parts of a semiconductor substance and thereafter a strip-shaped transducer-arrangement to at least therewith taking place of evaporation of the fluidic support-medium and in the thereafter located strip-shaped discharge-section of this block under the establishing of a (sub) micrometer high layer of parts of a semiconductor substance on the successive, uninterruptedly displacing semiconductor substrate-sections underneath.

FIG. 1A shows thereby the upper split-section, located underneath this medium-supplygroove.

FIG. 1B shows the upper split-section, located underneath the front-section of this transducer-arrangement.

FIG. 1C shows the upper split-section, located underneath the mid-section of this transducer-arrangement.

FIG. 1D shows the upper split-section, located underneath the rear-end of this transducer-arrangement.

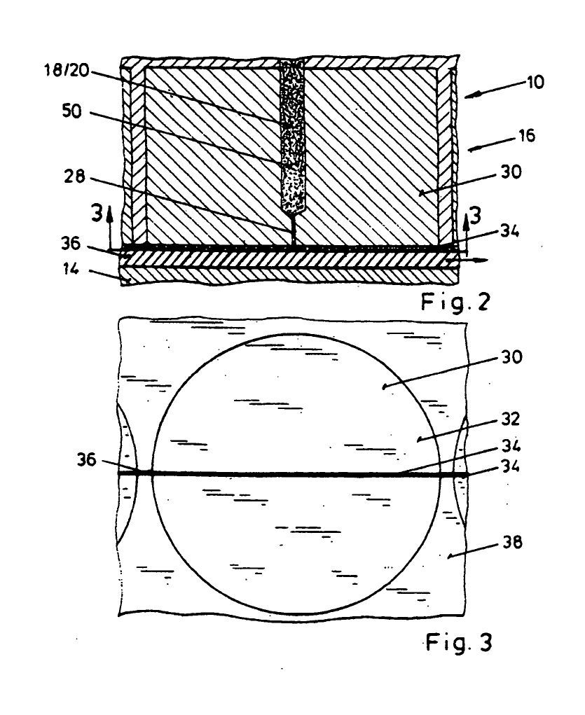

FIG. 2 shows very enlarged a lower section of the uppertunnelblock, wherein the insertion of a mini cylindrical medium-supplyblock for the medium supplygroove-arrangement according to FIG. 2.

FIG. 3 shows the cross-section over the line 3-3 of the medium-supplyblock according to FIG. 2.

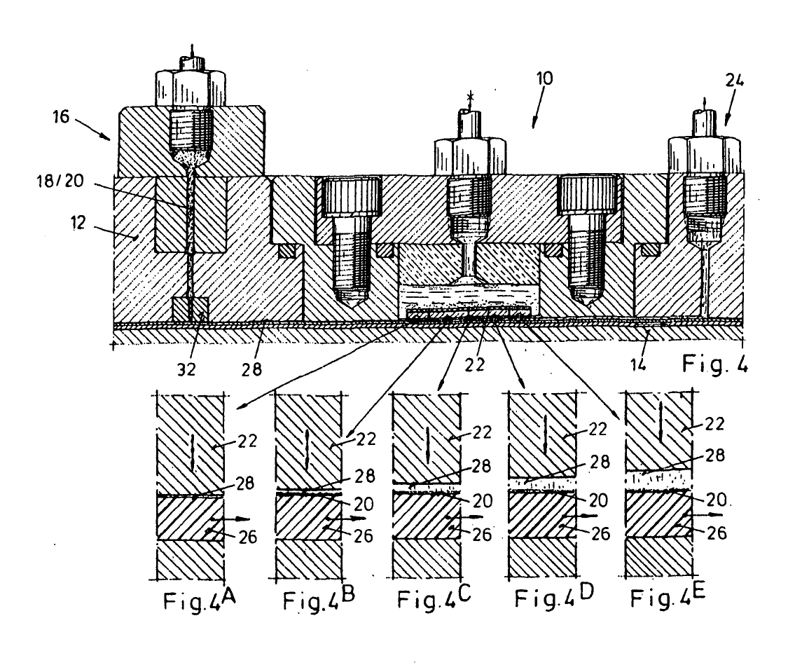

FIG. 4 shows a section of this tunnel-arrangement, whereby in this uppertunnelblock the location of a strip-shaped medium supply-arrangement to maintain an uninterrupted minimal supply per second of the combination of fluidic support-medium and particles of a semiconductor substance and a following strip-shaped transducer-arrangement to uninterruptedly taking place in its front-section of an inversion-process of these particles into the semiconductor top-layer of the central semiconductor processing-section of the successive semiconductor substrate-sections and in the following section of the underneath thereof located upper split-section the uninterruptedly taking place of deposition thereon of these particles under the establishing of a typically nanometer high layer thereof on these successive substrate-sections.

FIG. 4A shows thereby very enlarged the section of this uppersplit, located underneath the front-part of this transducer and wherein the taking place of at least also an insertion-process of these particles.

FIG. 4B shows thereby a following section of this uppersplit and wherein mainly the taking place of deposition of these particles.

FIG. 4C shows a following uppersplit-section, with therein a further deposition of these particles and a discharge of the evaporated support-medium through an increased height of this uppersplit.

FIG. 4D shows a following section of this uppersplit and wherein the taking place of the last phase of such deposition of these particles.

FIG. 4E shows the uppersplit-section under the end-section of this transducer and wherein almost only the taking place of an optimal discharge of the vaporized fluidic support-medium through a split-section with a maximal height thereof.

FIG. 5 shows very enlarged a lower part of the uppertunnelblock, whereby in the central section thereof the location therein of a mini cylindrical medium-supplyblock and in its bottom wall the location of an in transverse direction of the tunnel-passage, uninterruptedly extending nanometer wide and micrometer high medium-supplygroove.

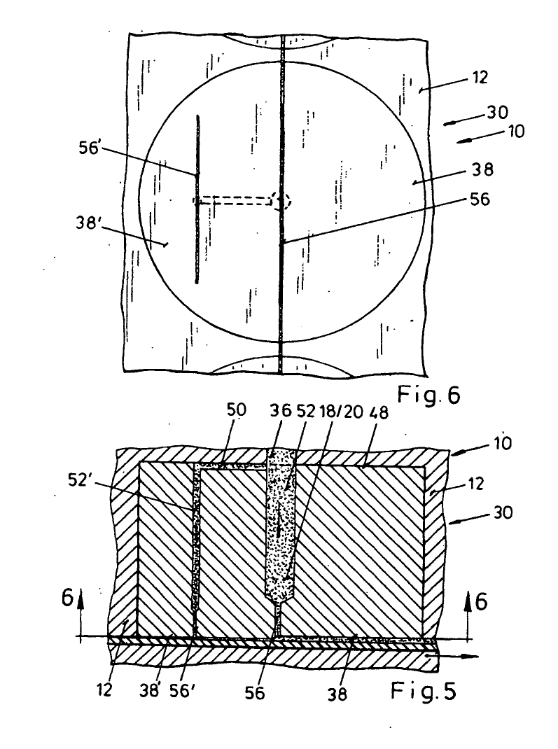

FIG. 6 shows the cross-section along the line 6-6 of the mini supply-block according to the FIG. 5.

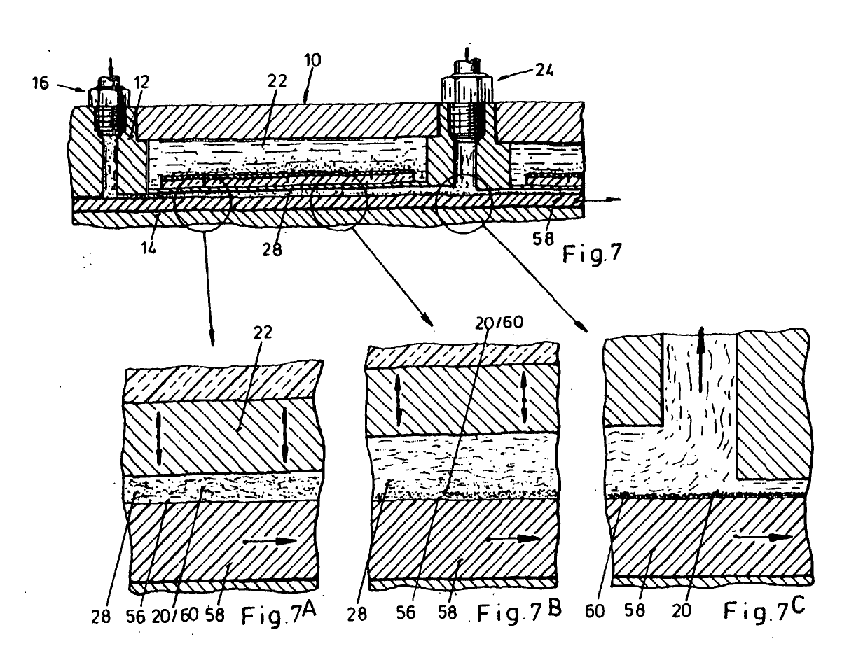

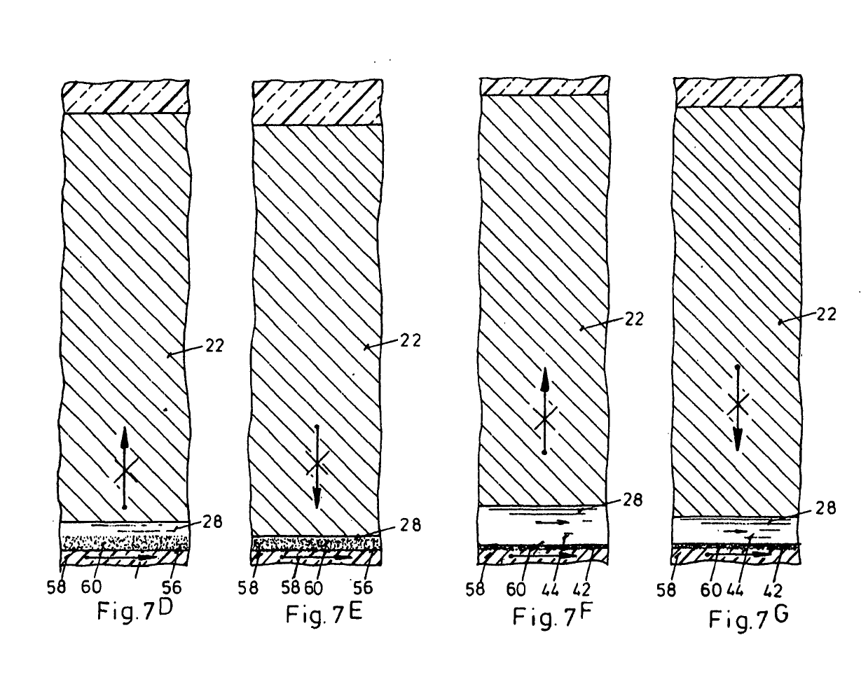

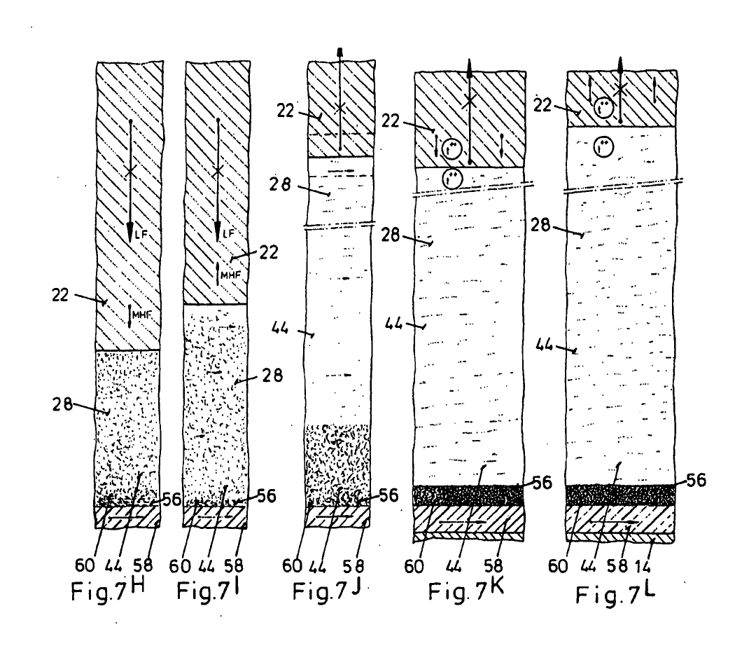

FIGS. 7 and 7A, B and C show by means of the strip-shaped transducer in the uppertunnelblock the uninterruptedly taking place of the successive phases of an anchorage-process of parts of a solid semiconductor substance in combination with the establishing of a nanometer high layer thereof on the successive semiconductor semiconductor substrate-sections, uninterruptedly displacing underneath.

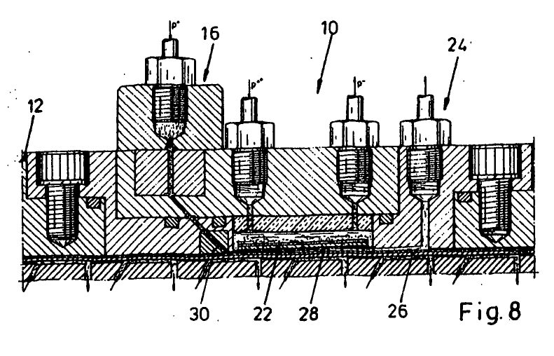

FIG. 8 shows by means of the strip-shaped transducer in the uppertunnelblock the uninterruptedly taking place of successive phases of a anchorage-process of parts of a fluidic semiconductor stitch-substance within the top-layer of the successive, uninterruptedly displacing semiconductor substrate-sections under the establishing thereupon of a nanometer high layer thereof.

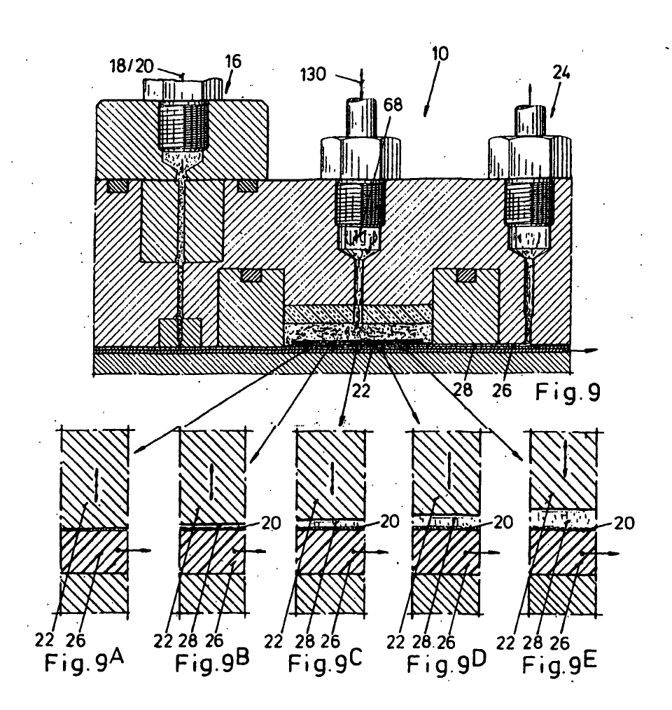

FIGS. 9 through E show very enlarged the by means of the strip-shaped transducer in the uppertunnelblock taking place of successive phases of the establishing of a micro-meter high layer of parts of a semiconductor substance in a solid and/or fluidic form thereof onto the successive semiconductor substrate-sections, passing underneath, and such under the combination of the thereby continuously maintaining of the combination of a low-frequency pulsating- and a megasonic vibrating-condition thereof.

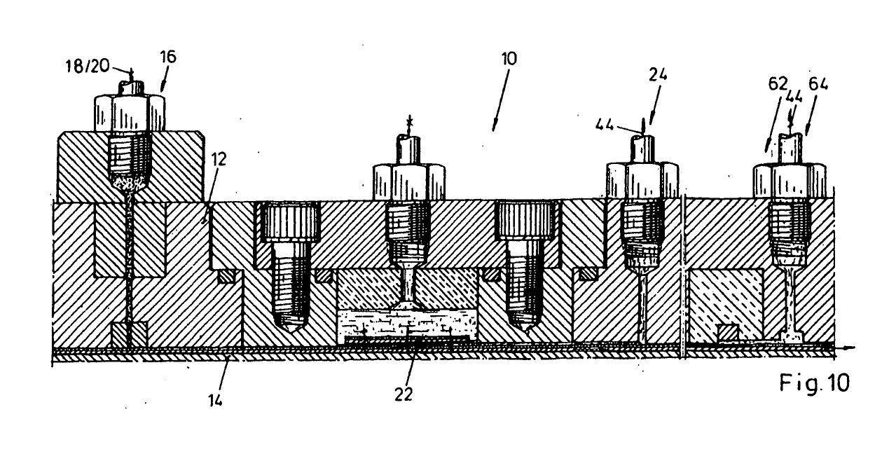

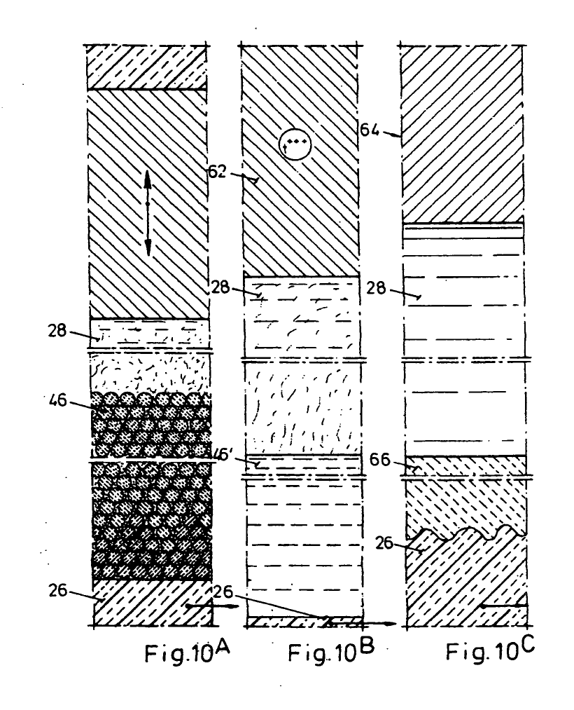

FIG. 10 shows a section of the tunnel-arrangement according to FIG. 1, with thereby in the uppertunnelblock behind this strip-shaped transducer arrangement and the following strip-shaped discharge-section for the evaporated support-medium the location of a strip-shaped heating-element in behalve of the uninterruptedly taking place of an oven-treatment of the on the successive, underneath uninterruptedly displacing semiconductor substrate-sections applied particles of a solid semiconductor substance, FIG. 10A, under the establishing of a layer in a fluidic form thereof, FIG. 10B, and in the following strip-shaped cooling-off section, FIG. 10C, the taking place of a cooling-off process of the fluidic layer under the establishing of a micrometer high layer of this substance in a solid form thereof.

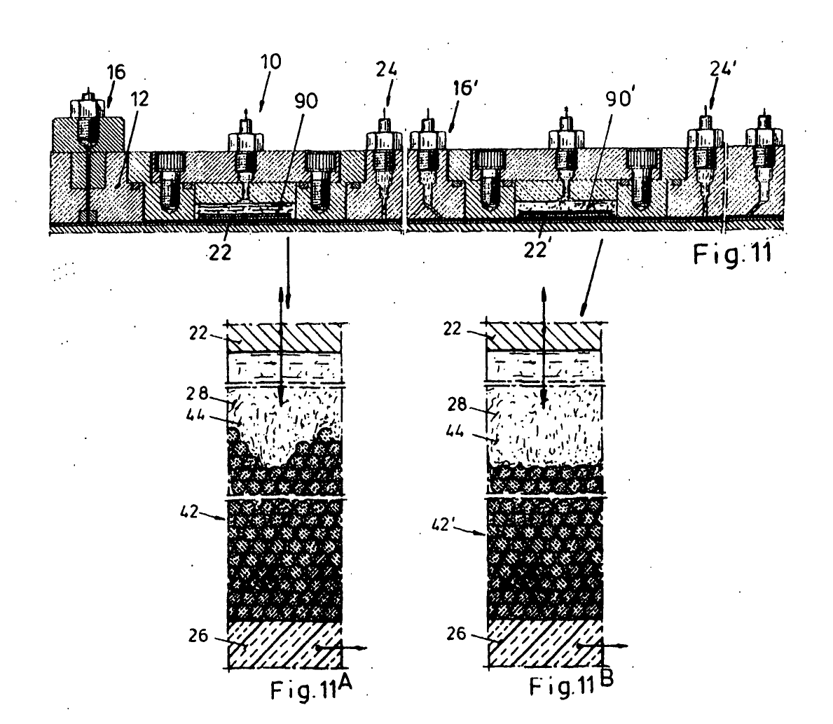

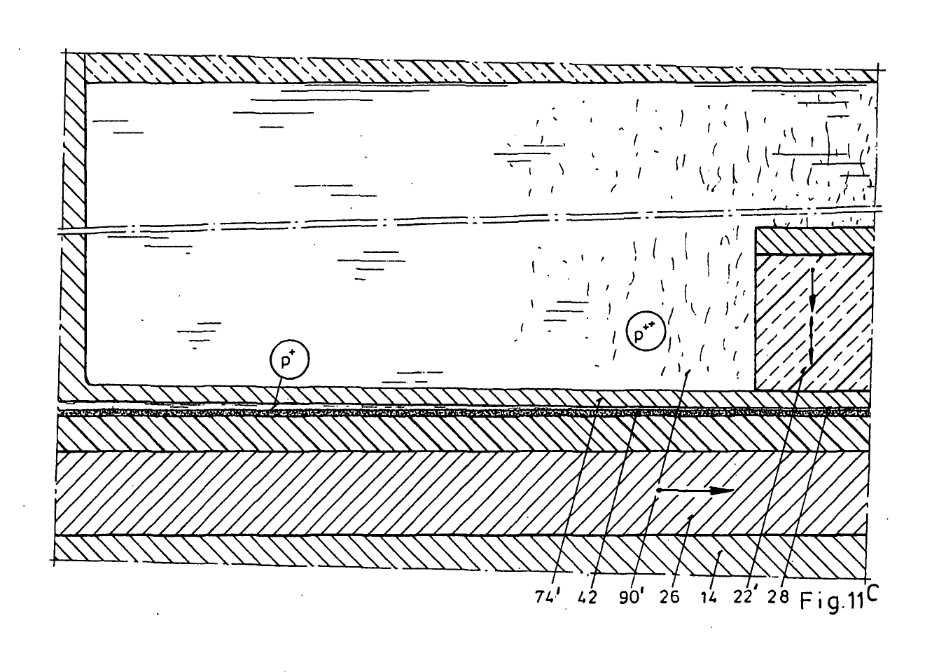

FIG. 11 shows a section of the tunnel-arrangement according to FIG. 1, and whereby in the uppertunnelblock behind this strip-shaped transducer-arrangement and the following strip-shaped medium discharge-section the location of a second discharge-section the location of a second strip-shaped transducer-arrangement on behalve of the therewith uninterruptedly taking place of a flatness-process of the under such a first transducer-arrangement established micrometer high layer of parts of a solid semiconductor substance, as very enlarged is shown in the FIGS. 11A and 11B.

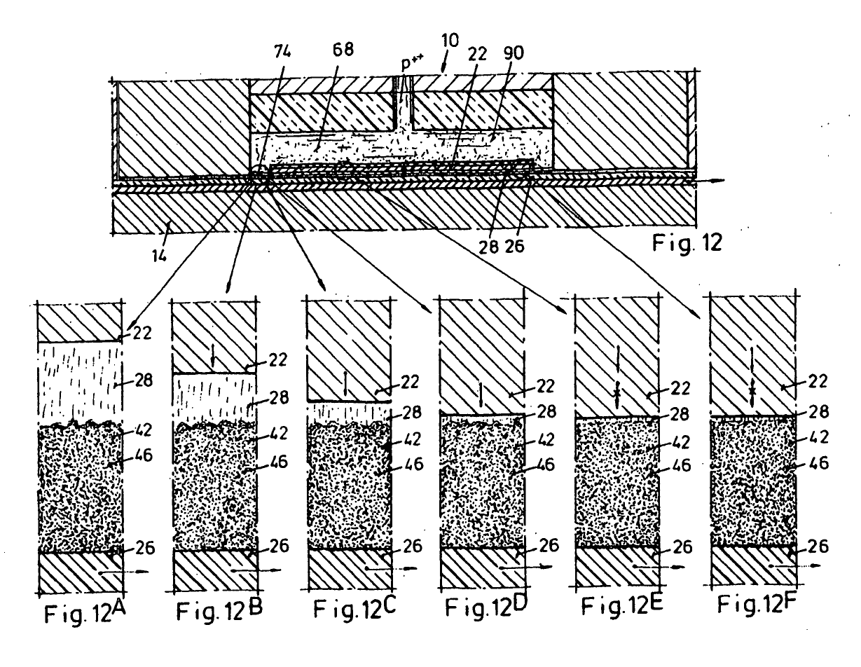

FIG. 12 shows also again the second transducer arrangement and whereby in the FIGS. 12A through F the disclosure of the successive phases of this flatness process, with at least underneath the back-side thereof the established ultra flat condition of the supplied micrometer high layer of parts of a solid semiconductor substance on the successive semiconductor substrate-sections, displacing underneath.

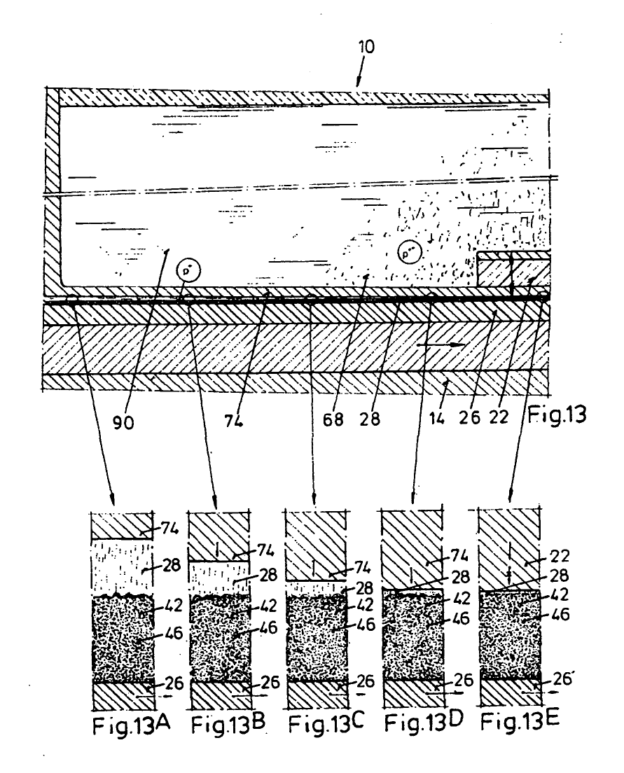

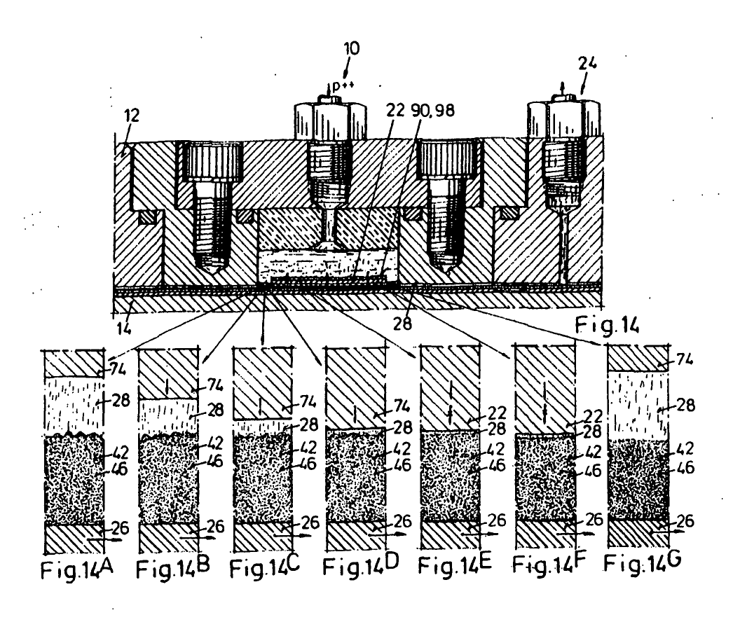

FIG. 13 shows the front-section of the transducer-arrangement according to FIG. 12 at the location of the membrane-section thereof and whereby by means of a small over-pressure of the in the transducer-compartment located medium with regard to the pressure of the medium in the upper split-section, located underneath, the maintaining of a pressed-upon position of this transducer under vibration-condition on the supplied layer of a semiconductor substance to establish such an optimal flatness-process, as also enlarged is shown in the FIGS. 13A through E.

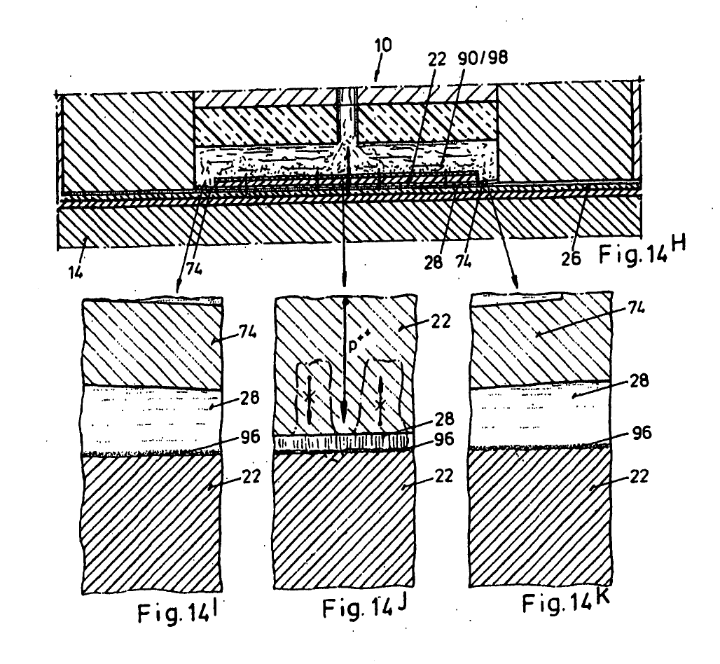

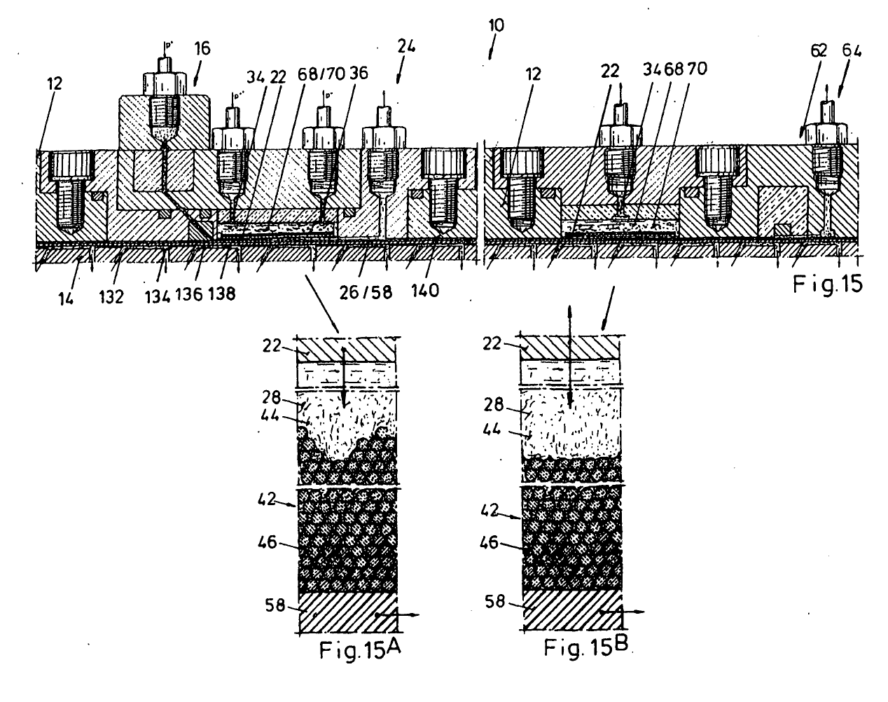

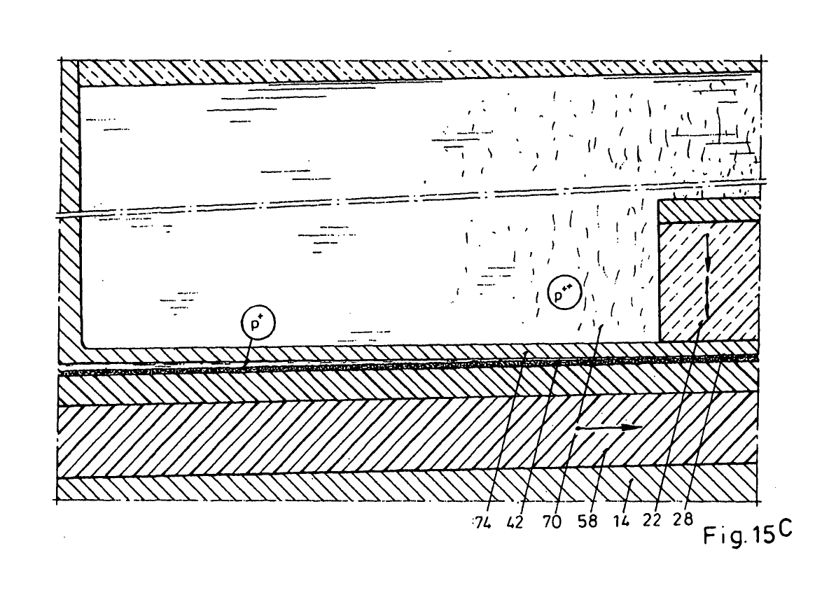

FIG. 14 shows the second transducer-arrangement and whereby by means of in this transducer-compartment maintaining of a small over-pressure of the therein existing typically gaseous medium with regard to the pressure of the medium in the upper split-section, located underneath the uninterruptedly maintaining of a pressed-upon position of the therein located transducer under a vibration-condition on the in a foregoing tunnel-section applied micrometer high layer of parts of a semiconductor substance in a solid form thereof to therein take place of an optimal flatness-process, and in the FIGS. 14A through G very enlarged shown successive heights of the exceeding upper split-sections.

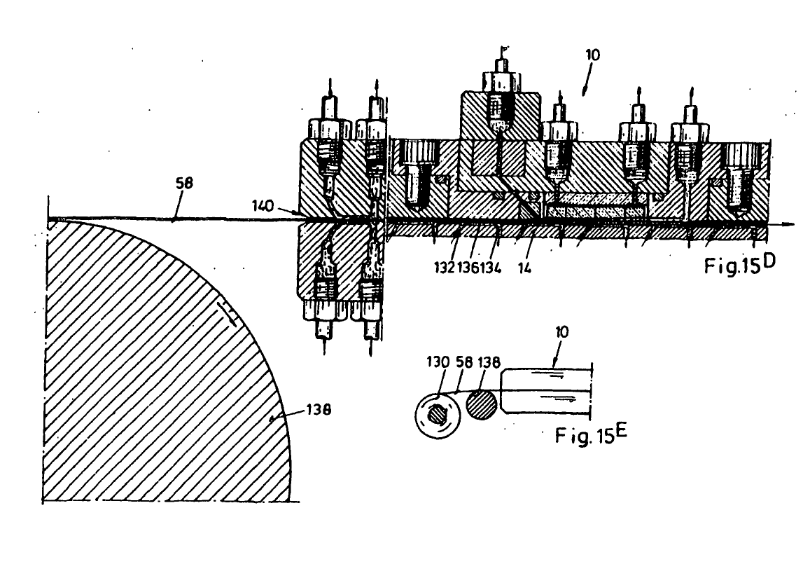

FIG. 15 shows a section of the tunnel-arrangement according to FIG. 1, and whereby in the uppertunnelblock behind this combination of a strip-shaped medium supply-section, -transducer-arrangement and -medium-discharge-section the location of a following combination of a strip-shaped medium-supplysection, -transducer-arrangement and medium-discharge section to accomplish by means of the second combination of a following micrometer high layer of particles of a solid semiconductor substance on the by means of this first combination established micrometer high layer of these particles, as very enlarged is shown in the FIGS. 15A and 15B.

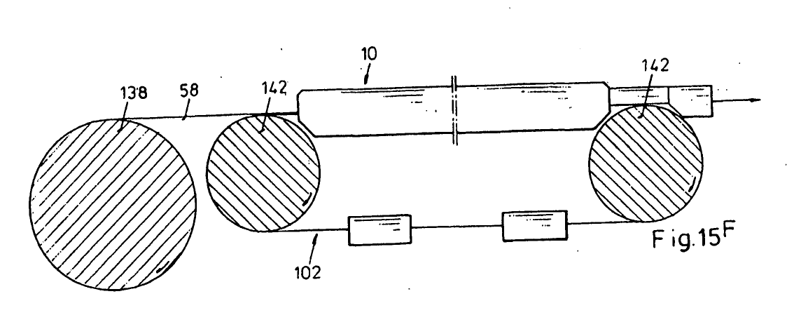

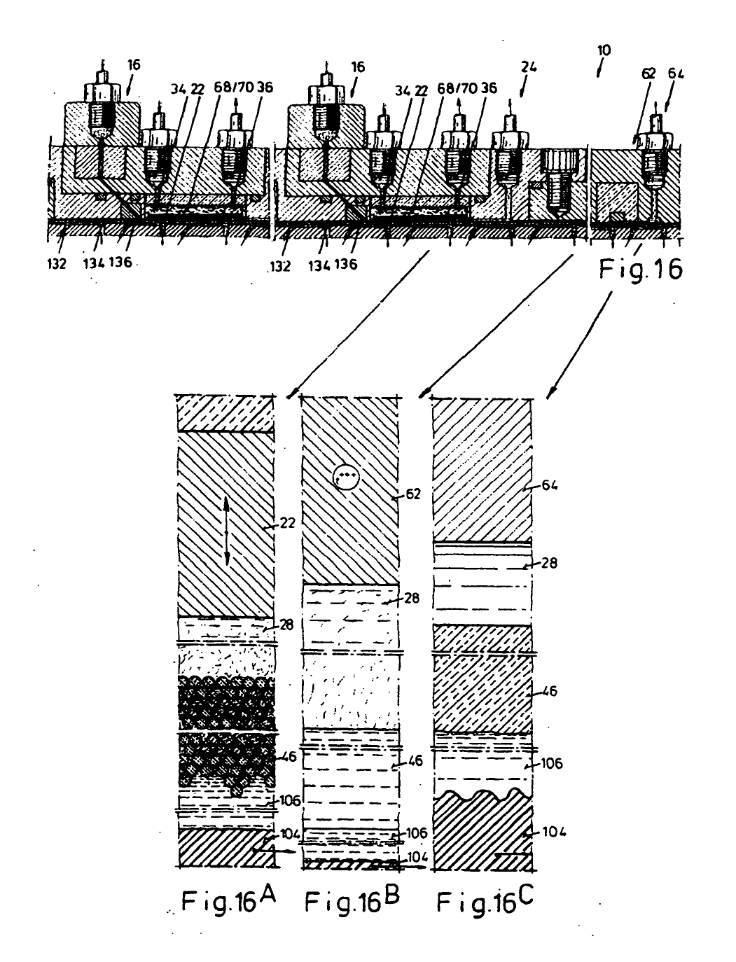

FIG. 16 shows a section of the tunnel-arrangement, whereby in the uppertunnelblock thereof the location of two successive combinations of a strip-shaped medium-supply-groove for particles of a solid semiconductor substance, transducer-arrangement and a strip-shaped medium-discharge-groove to built-up a micrometer high layer of at least these particles, with thereafter in this block the location of a strip-shaped oven-section and in a following discharge-section to accomplish a micrometer high solid layer of this semiconductor substance, as very enlarged is indicated in the FIGS. 16A, B and C.

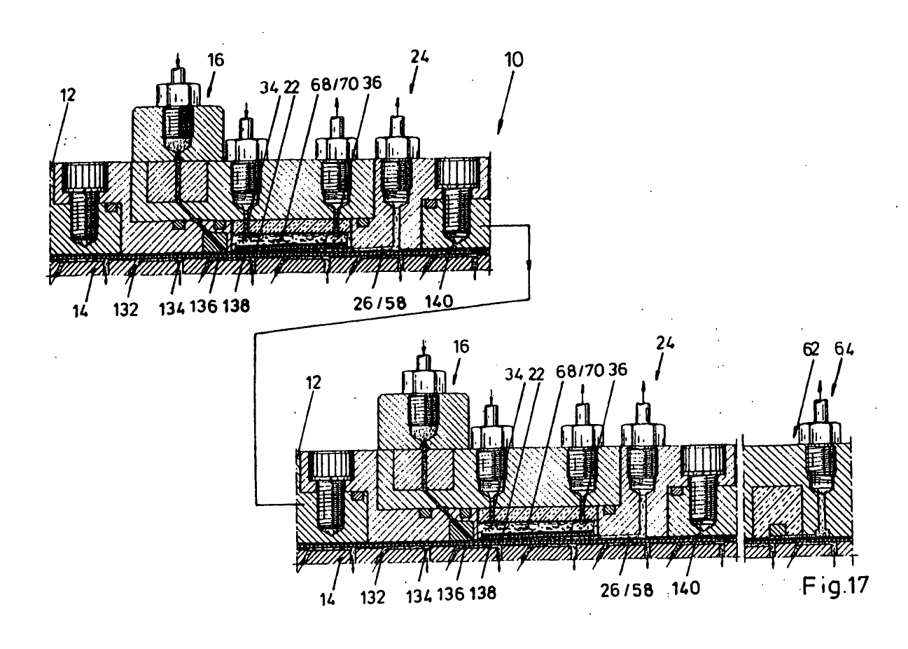

FIG. 17 shows again the combination of such a pair of successive transducer-arrangements, with thereafter the location of such a strip-shaped heating- and cooling-device, as already is shown in FIG. 16, and whereby by means of the first transducer the establishing of such di-electrical layer immediately upon the synthetic folio, as enlarged is shown in FIG. 17A, under the also therewith by means of the successive vibrations of the transducer taking place of affecting of the particles of such substance on the top-layer of this folio, under the following heating-element the transfer of this layer of solid particles into a fluidic layer, as is shown in FIG. 17B, and thereupon after its cooling-off in the following arrangement the accomplishing of a solid condition of this established layer under a sufficient anchorage thereof on this folio, as very enlarged is shown in FIG. 17C.

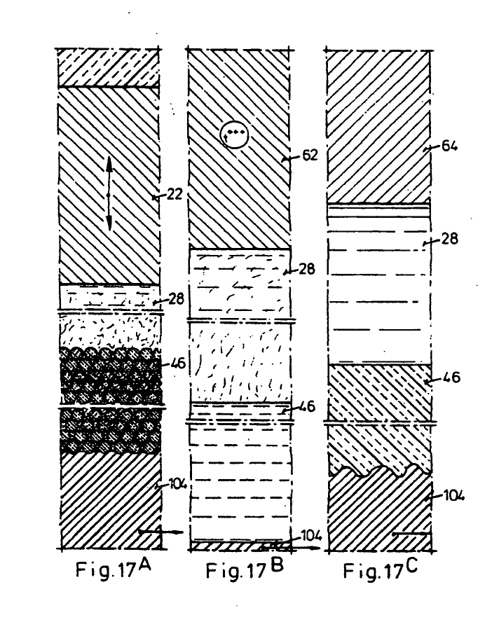

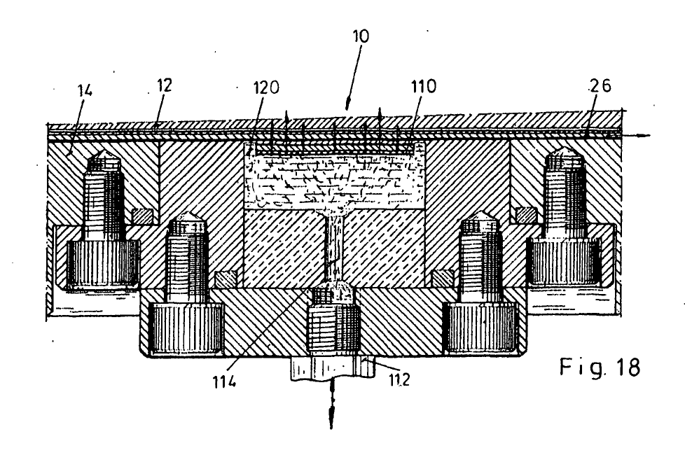

FIG. 18 shows in the tunnel-arrangement an exchangeable strip-shaped lower transducer-arrangement, contained within the lowertunnelblock, and whereby during the semiconductor treatment-process of the successive semiconductor substrate-sections the typically maintaining of the therein shown combination of a low-frequently pulsating/vibrating condition thereof, with by means of the in an electric vibration-arousing device aroused electrical vibrations and a very low-frequently pulsating condition thereof by means of the uninterrupted successive supply and discharge of gaseous medium through a central medium supply- and discharge channel toward and from the lower transducer-compartment.

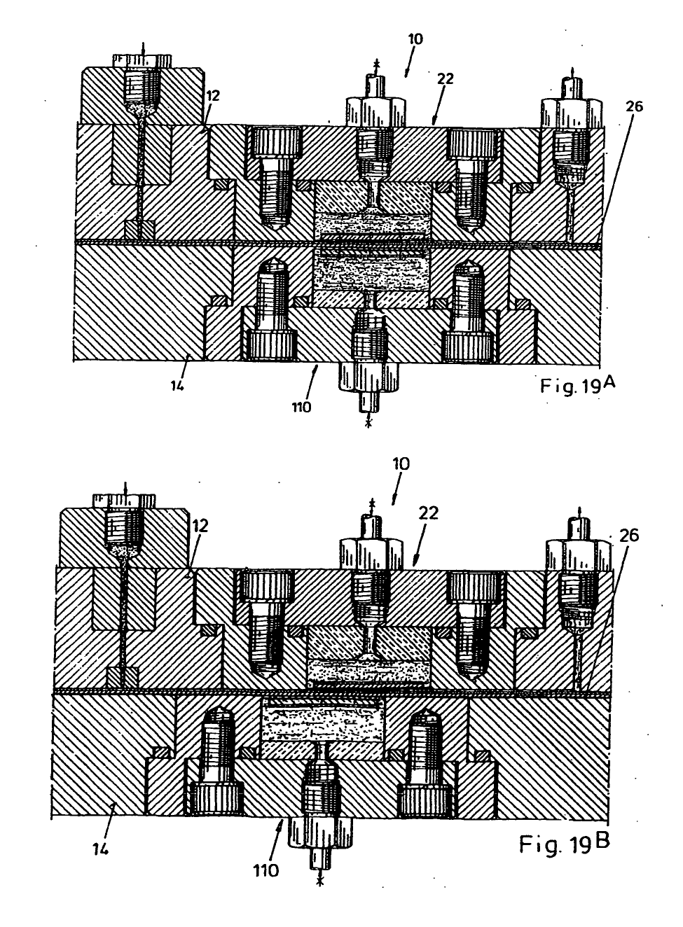

FIG. 19A shows the formation in this tunnel-arrangement of the combination of a strip-shaped upper transducer-arrangement, contained in the upper-tunnelblock, and the strip-shaped lower transducer-arrangement, contained underneath thereof in the lowertunnelblock, to maintain therewith a semiconductor treatment-process of the successive, uninterruptedly in-between displacing substrate-sections under the combination of a typically very high-frequently vibrating upper transducer and a typically low-frequently vibrating lower transducer.

FIG. 19B shows thereby in addition an alternative position of these transducer-arrangements, with the lower transducer forwardly displaced underneath this upper-transducer.

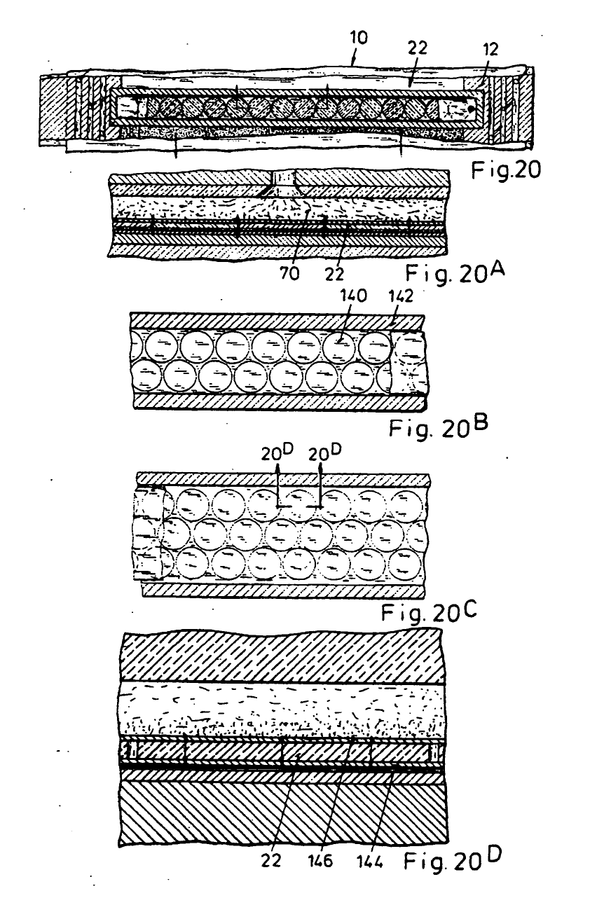

FIG. 20 shows an exchangeable strip-shaped transducer-arrangement, extending in transverse direction of the tunnel-arrangement over at least the central semiconductor treatment-section of the uppertunnelblock, and whereby this transducer-arrangement, contained in a compartment thereof, comprises a number of typically cylindrical mini transducers, arranged aside each other.

FIGS. 20A, B and C show a strip-shaped thin part of the lower wall of the exchangeable transducer-block, thereby at least also functioning as a lower electrode thereof and above a common upper electrode-plate, FIG. 20D, connected with a typically above this tunnel-arrangement located generator to arouse therein electrical vibrations for these transducers.

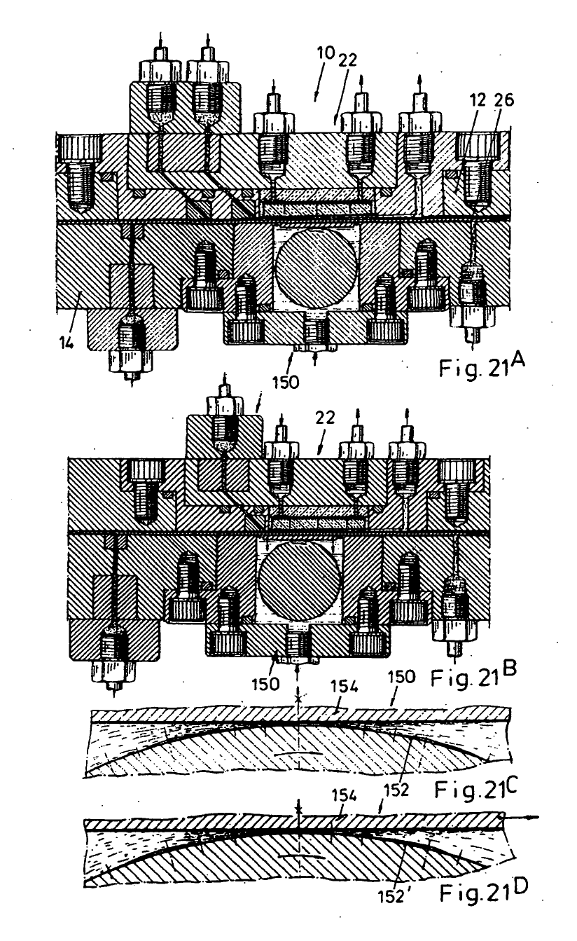

FIG. 21A discloses in a section of the tunnel-arrangement underneath the exchangeable strip-shaped transducer-arrangement, located in the uppertunnelblock, in the lowertunnelblock the location of an also exchangeable strip-shaped lower notchesshaft-arrangement to by means of this combination the maintaining of a semiconductor treatment of the successive, uninterruptedly displacing semiconductor substrate-sections in-between, with thereby the continuous maintaining of a typically at least UHF vibration condition of the upper transducer and a typically HF vibration-condition of the lower notchesshaft-arrangement.

FIG. 21B shows thereby a forwardly leaped position of this lower notchesshaft-arrangement with regard to this upper transducer-arrangement.

FIG. 21C shows for this notchesshaft-arrangement successive notches, whereby, as seen in the direction of rotation thereof, a considerable length and a thereupon followed small length thereof to by means of the strip-shaped press-on plate of this arrangement therewith successively maintaining of a slow upward- and a following fast downward displacement of these successive substrate-sections under the supporting therewith of a certain semiconductor treatment-process by means of the also established vibrating action of the successive substrate-sections therewith, as for instance a cleaning-, stripping-, etching- or rinsing-process of the top-layer thereof.

FIG. 21D shows for this notchesshaft-arrangement a small length and a thereupon following considerable length of such successive notches to enable by means of such press-on plate the successively maintaining of a fast upward displacement and a thereupon following slow downward displacement of these substrate-sections to support therewith a certain semiconductor treatment-process, as for instance the uninterruptedly deposition of particles of a semiconductor substance.

FIG. 1 shows a section of the tunnel-arrangement 10, whereby in the uppertunnelblock 12 thereof the location of a strip-shaped medium supplygroove-arrangement 16 to uninterruptedly supply the combination of fluidic support-medium 18 and parts 20 of a semiconductor substance and in a following section the strip-shaped transducer-arrange-went 22 to at least also the taking place of evaporation of this fluidic support-medium and in the following strip-shaped discharge-section 24 of this block, with the establishing of a (sub) micrometer high layer of particles 20 of such semiconductor substance onto the successive, uninterruptedly underneath displacing semiconductor substrate-sections 26.

FIG. 1A thereby shows the uppersplit-section 28 underneath this medium-supplygroove 16.

FIG. 1B shows the uppersplit-section 28 underneath the front-end of this transducer-arrangement 22, whereby typically the uninterruptedly taking place of an intrusion-process of these particles 20 in the upper layer 30 of the successive substrate-sections 26, displacing underneath, and the start of the evaporation-process of the support-medium 18.

FIG. 1C shows the mid-section of this transducer-arrangement 22 and whereby the already taking place of a deposition of these particles.

FIG. 1D shows the uppersplit-section 28 underneath the -back-side of this transducer 32 and whereby the accomplished deposition of at least all particles 20 of this semiconductor substance under the establishment of a micrometer high layer thereof.

FIG. 1E shows the upperspilt-section 28 underneath the medium-discharge groove 24.

FIG. 2 shows very enlarged the lower section of the uppertunnelblock 12, wherein the location of a mini cylindrical medium-supplyblock 30 for the medium supply-block 20 for the medium supply-groove-arrangement 16 according to FIG. 1.

FIG. 3 shows the cross-section over the line 3-3 of the supply-block 30 according to FIG. 2 and whereby in the lower part 32 thereof the location of a micrometer wide medium supply-groove 34, with the connection thereof on the adjacent medium supply-grooves 36 in the lower wall 38 of the uppertunnelblock 12 under the establishing of, one, uninterruptedly in transverse direction of the tunnel-arrangement extending supply-groove for the combination of fluidic support-medium 18 and parts 20 of a semiconductor substance at the central semiconductor treatment-section of the tunnel-arrangement.

FIG. 4 discloses a section of the tunnel-arrangement 10 and whereby in the uppertunnelblock 12 the location of a strip-shaped medium-supply device 16 to accomplish an uninterrupted minimal supply per second of the combination of fluidic support-medium 18 and particles of the semiconductor substance 20 and a following exchangeable strip-shaped transducer 22 to accomplish an uninterruptedly taking place of a penetration-process of these particles 20 in the semiconductor top-layer 40 of the central semiconductor treatment-section of the successive substrate-sections 26 and in the following sections of the upper-split 28 the uninterruptedly taking place of a further deposition thereon of these particles under the accomplishing of a typically sub-micrometer height layer of these particles thereon.

FIG. 4A shows thereby very enlarged the section of this top-split 28 at the entrance-section of this transducer 22 and wherein the taking place of at least such a penetration-process of these particles.

FIG. 4B shows thereby a following section of the upper-split 28 and wherein mainly the taking place of deposition of these particles 20.

FIG. 4C shows a following upper split-section, with therein a further deposition of these particles 20 and with a discharge of the vaporized support-medium through an increased height of the upper-split 28.

FIG. 4D shows a following upper split-section, with therein the taking place of the end-phase of such a deposition of these particles 20.

FIG. 4E shows the upper split-section under the end-section of the transducer 22 and wherein the almost excluding taking place of an optimal discharge of the vaporized fluidic support-medium and a maximal pacing-through height of the upper-split 28.

FIG. 5 shows very enlarged an alternative construction 30 of such a mini medium-supplyblock according to

FIG. 2.

Thereby in the upper wall of this block 30 the location of a mini-wide medium supply-channel 32′, connected with the central medium supply-channel 52 through the supply-groove 50 to also enable an uninterrupted supply therethrough of such combination of support-medium 18 and parts of the semiconductor substance 20 toward the secondary micro-wide medium supply-grooves 56′ in the lower wall 38 of this block and parallel is located with the medium supply-grooves 56.

Thereby also an larger height of the lower wall-section 38 beyond this main groove 56 than of the secondary part 38′ of this block 30 thereafter.

FIG. 6 shows thereby a horizontal lower view upon the lower wall of the uppertunnelblock 12 at the location of this block over the line 6-6, with therein the position of these aside each other located supply-grooves 56 and 56′.

FIGS. 7 and 7A through 1 show by means of the strip-shaped transducer 22, located in the uppertunnelblock 12, the uninterruptedly taking place of the successive phases of an anchorage-process of the particles 20 of the semiconductor substance 60 in combination with the gradually establishing of a micrometer high layer thereof on the upper-wall 56 of the successive, uninterruptedly underneath displacing typically synthetic folio-sections 58.

Such is very enlarged shown in the FIGS. 7A, B and C.

Furthermore, in FIG. 7D at the front-part of this transducer the highest vibrating position, with still a micrometer high section of the upper-split 28 and the thereby taking place of an optimal penetration/anchorage-process of these typically fluidic parts 60 in the upper wall 56 of this synthetic folio 58, displacing underneath.

FIGS. 7F and G show during the successive top- and lowest-vibrating position of this transducer 22 at the back-side thereof, with a considerable height of the sections of the upper-split 28, located underneath, and whereby by means of evaporation of the fluidic support-medium 60 the accomplishing of a micrometer high layer of these parts of the fluidic substance 60, with the vaporized medium 44 displacing over it.

Furthermore, FIGS. 7H through L show very enlarged such phases of penetration and deposition of such particles of the fluidic stitch-substance 60 on these successive folio-sections 58 by means of such a vibrating upper-transducer 22 and whereby a fast downward- and a following slow upward displacement of this transducer 22 is shown and such to also an optimal establishing of such a penetration-action of these particles 60 into the upper wall 56 of these successive folio-sections 58 under the also establishing of a typically nanometer high layer of these particles.

FIG. 8 shows in a strip-shaped section of the upper-tunnelblock 12 the location of the combination of a strip-shaped upper-transducer 22 and the strip-shaped alternative medium supply-device 16 in front of it and the thereafter located strip-shaped medium discharge-device 24.

Thereby the location of the mini strip-shaped medium supply-block 30 of this medium supply-device 16 immediately in-front of this transducer 22 and whereby also an increased height of the upper split-section 28 toward the medium discharge-device 24 above the successive substrate-sections 26, displacing underneath.

FIG. 9 again discloses such a combination of the strip-shaped upper-transducer 22, located in the uppertunnelblock, and the strip-shaped supply-device i6 in front of it, for the combination of fluidic support-medium 18 and particles of a semiconductor substance 20.

Thereby through the supply-channel 130 as the uninterruptedly taking place of successive low-frequently supply and discharge of gaseous medium 68 toward and from the upper transducer-compartment to maintain the combination of a vibrating- and pulsating-condition of this transducer.

Such a gradually establishing of a micrometer high layer of these particles 20 is shown very large increased in the FIGS. 9A through E, with the indication therein of the lowest low-frequent pulsation-position of this vibrating transducer.

This gradually establishing of a layer under the application of typically a solid semiconductor substance thereby is taking place without at at-least the back-side of this transducer by means of the maintaining of such a vibration-condition the taking place of a stitching of such particles against the lower electrode-plate thereof.

FIG. 10 shows a section of this tunnel-arrangement 10 according to FIG. 1, with thereby in the uppertunnelblock 12 behind this strip-shaped transducer-arrangement 22 and the succeeding strip-shaped discharge-section 24 for the evaporated support-medium 44 the location of the strip-shaped heating-element arrangement 62 to uninterruptedly taking place therewith of an oven-treatment of the particles 46 of a solid semiconductor substance, applied on the successive, uninterruptedly underneath thereof displacing successive semiconductor substrate-sections, FIG. 10A, under the establishing of the layer 468 in a fluidic form thereof, FIG. 10B, and in a following strip-shaped cooling-off section 64, FIG. 10C, the taking place of a cooling-off process of this fluidic layer under the creation of a micrometer high layer of this substance in the solid form 66 thereof.

Thereby this established layer 66 is almost sufficiently anchoraged onto the di-electric under-layer, as is also shown in this Figure.

Furthermore, for such particles the possible use of any other semiconductor substance in a solid form thereof.

Thereby this established layer 66 is also sufficiently anchoraged onto this di-electric under-layer, as also is shown in this Figure.

Furthermore, for such particles the possible use of any other semiconductor substance in a solid form thereof.

FIG. 11 shows a section of the tunnel-arrangement 10 according to FIG. 1 and whereby in the uppertunnelblock 12 behind this strip-shaped transducer-arrangement 22 and the following strip-shaped medium discharge-section 24 the location of a second strip-shaped transducer-arrangement 22′ on behalf of therewith an uninterrupted flatness-process of the underneath this first transducer-arrangement 22 established micrometer high layer 42 of particles of a solid semiconductor substance, as very enlarged is shown in the FIGS. 11A and B.

FIG. 11C shows thereby enlarged the front-section of this second transducer 22′, contained in the transducer-compartment 90′, with around thereof the thin-walled metal membrane-section 74 as part of the lower-electrode thereof.

During the working of this tunnel-arrangement in the compartment 90′ the maintaining of a higher pressure of the therein located gaseous medium with regard to the pressure of the medium in the uppersplit-section 28 underneath this transducer, its also functioning as a strip-shaped press-on wall, with thereby the maintaining of a downward displacement thereof, because these membrane-sections 74′ for that purpose have a sufficiently small thickness thereof.

Thereby during such a flatness-process by means of this transducer 22′ subsequently at least locally, typically the front-end thereof, the maintaining of an urged upon condition thereof on the supplied layer 42 under the vibrating action thereof and underneath thereof the displacement of the successive substrate-sections 26 over the section of the lowertunnelblock 14, located underneath, with a downward thrust thereupon.

FIG. 12 shows again such a second transducer-arrangement 22′ and whereby in the FIGS. 12A through F very enlarged thereby the successive phases of an alternative flatness is shown, with at the end underneath the back-section thereof, FIG. 12F, the accomplishment of an ultra-flat condition of the applied micrometer high layer 42 of the particles 46 of a solid semiconductor substance on behalve of an optimal flatness-process, as very enlarged is shown in the FIGS. 13A through E.

FIG. 14 shows again such a second transducer 22 and whereby by means of the maintaining of a small over-pressure of the in the transducer-compartment 90 present typically gaseous medium 98 with regard to the pressure of the medium in the upper split-section 28, present underneath, the uninterruptedly maintaining of a pressed-upon position of this therein located transducer 22 under a vibration-condition thereof on the in the foregoing tunnel-section established micrometer high layer 42 of particles of the semiconductor substance 46 in a solid form thereof on behalve of the taking place therein of an optimal flatness-process.

Thereby FIGS. 14A through G show very enlarged the successive heights of the successive upper split-sections 28 under the establishing therein of an ultra-uniform height of such an established, typically possibly even a nanometer high layer of a fluidic substance.

FIG. 14 H shows again such a second transducer, arrangement 22 in an adapted form thereof and whereby the FIGS. 14I, J and K very enlarged show the successive positions of this upper-split-section 28;

a) in FIG. 14I the position thereof underneath the membrane-section 74 near the front-side of this transducer, with a maximum height thereof;
b) in FIG. 14J the position thereof at the central transducer-section, with a mini height thereof; and
c) in FIG. 14K the position thereof underneath the membrane-section 74 near the back-side of this transducer, with also a maximum height thereof.

FIG. 15 shows a strip-shaped section of the tunnel-arrangement 10 and whereby in the uppertunnelblock 12 behind a foregoing tunnel-section, wherein already by means of a transducer-arrangement the accomplishing of a layer of particles of a di-electric substance, again the location of the strip-shaped medium supply-section 16, the transducer-arrangement 22, located in the transducer-compartment 70, containing gaseous medium 68, with thereby the uninterrupted supply thereof through the supply-conduit 34 and the discharge thereof through the discharge-conduit 36.

Furthermore, in the lowertunnelblock 14 the location of successive combinations of the strip-shaped supply-groove 132 for typically fluidic transfer-medium 138, the strip-shaped discharge-groove 134 and the in-between located transfer-grooves 136, on behalf of the support of the linear displacement of the successive synthetic folio-sections 58 through the tunnel passage-section 140.

Furthermore, in this uppertunnelblock behind this transducer-arrangement the location of the medium discharge-section 24.

Such an arrangement on behalf of the therein establishing of a following micrometer high layer of the particles 46 of a solid semiconductor substance on such an already established layer 42 of this substance as part of a semiconductor underlayer of the successive substrate-sections 26 and such under the thereby already taking place of a sufficient flatness-process of these established layers, as very enlarged is shown in FIG. 15A.

Thereby behind this first tunnel-section the location of a following tunnel-section, wherein also the insertion of at least such a transducer-arrangement 22 on behalf of the also therewith taking place of an optimal flatness-process of this total-layer, as also very enlarged is shown in FIG. 15B.

FIG. 15C shows furthermore very enlarged the front-section of this second transducer 22 at the front membrane-section 74 and whereby underneath in the lowertunnelblock 14 as an alternative no insertion in the upper wall thereof of such successive combinations of supply- and discharge-grooves of fluidic medium.

Furthermore, thereby in the transducer-compartment 70 the maintaining of a limited over-pressure of the gaseous medium on behalf of the thereby maintaining of a vibrating pressed-upon condition of this transducer against the supplied total-layer 42 of such particles of a di-electric substance on behalf of the at least assisting of such an optimal flatness-process.

FIGS. 15D and E show the front-section of the semiconductor transfer/treatment-tunnel 10, containing near the entrance thereof the storage-roll 130 for a very long, thin synthetic folio 58 as typically a definitive semiconductor underlayer of the successive, uninterruptedly displacing substrate-sections 26 therethrough, and means on behalf of the during its operation the displacement thereof by means of the in the upperwall of the lowertunnelblock 14 at least contained successive strip-shaped supply-grooves 132 for typically gaseous medium, such as N₂, with the transit thereof through a large number of aside each other located medium transmit-grooves 136 toward the strip-shaped discharge-grooves 134.

Further thereby the usage of the applying of the folio guidance-roll 138 between this storage-roll 130 and the entrance 140 of this tunnel-arrangement.

As an alternative, as is indicated in FIG. 15F, the appliance of the successive folio-sections on the uninterrupted metallic semiconductor substrate support/transfer-band 102, with a roll-arrangement near the entrance- and exit of the tunnel-arrangement, and shown and described in multiple, at the same time submitted Dutch Patent-applications of the applicant.

FIG. 16 shows a section of the tunnel-arrangement 10, whereby in the uppertunnelblock thereof the location of two successive exchangeable strip-shaped transducer-arrangements.

Thereby by means of this first transducer-arrangement 22 the establishing of an at least nanometer high layer of particles of typically a contemporary removable stitch-substance on the synthetic folio 104 and by means of the second transducer-arrangement 22 the applying of these fluidic particles upon this accomplished layer 46 under in addition also the therewith taking place of a flatness-process of this established layer 42, as very enlarged is shown in FIG. 16A.

FIG. 16B discloses thereby by means of the strip-shaped heating device 62 the melting of this layer 46.

FIG. 16C discloses further by means of a thereupon following cooling-off of this fluidic layer 46 by means of the strip-shaped cooling-off device 64 the establishing of an ultra-flat micrometer high layer 36 in a solid form thereof on the still fluidic temporary stitch-layer 106.

At the end of this total semiconductor treatment-process of these successive substrate-sections 16 in a device behind this tunnel-arrangement the taking place of a removal of the successive semiconductor substrate-sections from this folio 104, with thereafter in a following device the removal therefrom of the fluidic particles, still located thereon, with thereafter in a following strip-shaped device by means of a dividing-process thereof the accomplishing of semiconductor chips with a di-electric underlayer thereof.

As a possible alternative the application of such fluidic stitch-substance, that thereby the following is taking place:

a) such a typically at least nanometer high layer of stitch-substance is definitively anchored on this synthetic folio; and
b) such an established di-electrical layer thereby is definitively anchored on this stitch-substance.

Furthermore, as a possible alternative instead of such a di-electrical substance the application of another substance, as for instance a metallic substance, on behalf of the accomplishing of a metallic underlayer for these successive semiconductor substrate-sections, from which by means of dividing the obtaining of semiconductor chips with a metallic underlayer thereof.

Furthermore, as a following possible alternative instead of such a synthetic folio as a temporary semiconductor underlayer of the successive substrate-sections during their displacement through this tunnel-arrangement the application of a metallic folio or an uninterrupted metallic semiconductor support/transfer-band.

FIG. 17 again shows the combination of such two successive transducer-arrangements 22, with thereafter the location of the strip-shaped heating- and cooling-devices 62 and 64, as already is shown in FIG. 16, and whereby by means of the first transducer 22 the establishing of such a di-electric layer immediately upon the synthetic folio 104, as very enlarged is shown in FIG. 17A, under the thereby also by means of the successive vibrations of this transducer, typically the maintaining of the combination of a fast, downward displacement, with thereby a relatively large vibration-amplitude.

Thereupon a following slow upward displacement, with a relatively small vibration-amplitude of the successive transducer-vibrations, as also is shown in this Figure, with the optimal taking place of an affecting with these particles 46 of such a substance upon the top-layer of this folio 104.

Thereby underneath the following heating-device 62 the conversion of this layer of solid particles in a fluidic layer, as also very enlarged is shown in FIG. 17B, and subsequently after a cooling-off thereof in the following cooling-off device 64 the accomplishing of a solid condition of this applied layer 64 under an already sufficiently anchorage thereof on this folio 104, as very enlarged is is shown in FIG. 17C.

As a result, at the exit of this tunnel-arrangement the obtaining of successive substrate-sections, from which in a device behind thereof by means of division the accomplishment of semiconductor chips with a synthetic underlayer thereof.

FIG. 18 shows in the tunnel-arrangement the exchange-able strip-shaped lower transducer-arrangement 110, contained in the lowertunnelblock 14, and whereby its transducer is located underneath the central semiconductor treatment-section of the tunnel-passage.

Thereby during the therewith taking place of the at least contribution in a certain semiconductor treatment-process of the successive, uninterruptedly displacing semiconductor substrate-sections 26 above it, the typically continuously maintaining of the shown combination of a very low-frequent pulsating-condition by means of the uninterruptedly successively supply- and discharge of gaseous medium 114 through the central medium supply- and discharge-channel 112 toward and from the lower transducer-compartment 120 and the in such an electric vibration-generating device generated electrical vibrations.

FIG. 19A discloses the arrangement in the tunnel-arrangement 10 of the combination of a strip-shaped upper transducer-arrangement 22, contained in the uppertunnelblock 12, and its strip-shaped lower transducer-arrangement 110, located underneath in the lowertunnelblock 14, on behalf of the with this combination maintaining of a semiconductor treatment-process of the successive, uninterruptedly displacing substrate-sections 26 in-between, under the combination of a typically very high-frequently vibrating upper-transducer and a typically high-frequently vibrating lower-transducer.

FIG. 19B thereby also discloses an alternative application of these transducer-arrangements, with the lower-transducer 110 forwardly displaced underneath this upper-transducer 22 on behalf of the therewith typically maintaining of such semiconductor treatment-process under however an adapted condition thereof.

FIG. 20 shows an exchangeable strip-shaped transducer 22, extending in transverse direction of the tunnel-arrangement 10 over at least the central semiconductor treatment-section of the uppertunnelblock 12 and whereby this transducer-arrangement, located in the compartment 70, containing a number, in transverse direction aside each other positioned typically cylindrical transducers 140, FIGS. 20B and C, with a strip-shaped thin-walled section of the lower wall of the exchangeable transducer-block, at least also functioning as the lower electrode 144 thereof, and above thereof a common upper electrode-plate 146, FIG. 20D, connected with a typically above this transducer located electrical generator on behalf of the generation therein of the desirable electrical vibrations for such transducer-arrangement.

FIG. 21A shows in a section of the tunnel-arrangement 10 underneath the exchangeable strip-shaped transducer-arrangement 22, located in the uppertunnelblock 12, in the lowertunnelblock 14 the location of an also exchangeable strip-shaped lower notchesshaft-arrangement 150 on behalf of by means of this combination the maintaining of a semiconductor treatment-process of the successive uninterruptedly in-between displacing substrate-sections 26, with thereby a typically at least UHF vibration-condition of this transducer and a typically HF vibration-condition of this notchesshaft-arrangement 150.

FIG. 21B shows in addition a forwardly shifted position of this notchesshaft-arrangement 150 with regard to this transducer-arrangement 22.

FIG. 21C shows for this notchesshaft-arrangement 150 successive, in a radial direction separated notches 152, whereby, as seen in such shown direction, a considerable length and a following small length thereof on behalf of by means of the strip-shaped pressing-plate 154 the therewith successively maintaining of a slow upward- and a following fast downward displacement of the successive, uninterruptedly there-over displacing substrate-sections 26 under the therewith maintaining of a certain semiconductor treatment-process, as for instance a cleaning-, etching-, stripping- or rinsing-process of the top-layer thereof.

FIG. 21D shows thereby for this notchesshaft-arrangement a small length and a following considerable length of such successive notches 152′ on behalf of the by means of the pressing-plate 154 successively maintaining of a fast upward displacement of these there-over displacing substrate-sections and thereupon a slow downward displacing thereof on behalf of the therewith supporting of a certain semiconductor treatment-process, as for instance the deposition of particles of a semiconductor substance on the top-layer thereof.

Within the scope of the invention for this tunnel-arrangement the possibility of any other semiconductor treatment-process under at least also the use of such strip-shaped transducer-arrangement, as for instance is shown and described in the accompanying Patent-Applications.

Furthermore, as shown and described in several of these other simultaneously filed Patent-Applications with regard to such tunnel-arrangement the use therein of a during the working thereof uninterruptedly displacing semiconductor support- and transfer-band as an alternative for such a folio and whereby near the entrance- and exit-side of this tunnel-arrangement a roll-arrangement and means to rotate this roll-arrangement at the exit-side thereof.

Thereby the maintaining of a continuous displacement of this band through the tunnel-passages a temporary semiconductor underlayer of the therein established semiconductor substrate-sections.

1-136. (canceled)

137. A substrate transfer/processing tunnel-arrangement for transfer and processing of successive substrate-sections, comprising:
a) the combination of an uppertunnelblock and a lowertunnelblock, extending in longitudinal direction thereof; and
b) above this uppertunnelblock in longitudinal direction thereof the location of at-least one strip-shaped direction device, extending mainly in transverse direction on behalf of during its operation the uninterruptedly taking place of the supply of at-least a fluidic support-medium and particles of a substance in a solid or fluidic form toward strip-shaped uppersplit-sections above the successive underneath this block uninterruptedly displacing uninterrupted substrate-section.

138. The tunnel-arrangement according to claim 137, wherein for successive substrate-sections the application of an uninterrupted band or folio as an at-least temporary underlayer thereof.

139. The tunnel-arrangement according to claim 137, wherein in a foregoing strip-shaped section at at-least the central semiconductor processing-section thereof underneath this uppertunnelblock the uninterruptedly accomplishing of a micrometer height of the uppersplit-section.

140. The tunnel-arrangement according to claim 139, wherein in the lowersplit-section thereof the uninterruptedly maintaining of such a considerable suctioning-off condition of medium under such a high negative pressure of the therein present medium, that therein the establishing of an at-least (sub)-micrometer height of the thereupon following undersplit-section.

141. The tunnel-arrangement according to claim 139, wherein the uninterruptedly taking place of supply of the combination of low-boiling fluidic support-medium and parts of a semiconductor substance under at-least almost the same pressure as that of the medium, located in the strip-shaped micrometer high uppersplit-section.

142. The tunnel-arrangement according to claim 139, wherein the uninterruptedly taking place of supply of the combination of low-boiling fluidic support-medium and parts of a semiconductor substance under at-least almost the same pressure as that of the medium, located in the strip-shaped micrometer high uppersplit-section, typically a negative pressure thereof.

143. The tunnel-arrangement according to claim 142, wherein in the following section of this uppertunnelblock the location of a strip-shaped transducer-arrangement at at-least the central semiconductor processing-section thereof on behalf of at-least also the functioning thereof as a heating-source, the evaporation therewith of this low-boiling fluidic support-medium under a vibrating deposition of these particles of a semiconductor substance on these successive semiconductor substrate-sections, displacing underneath, as in this block behind this transducer-arrangement the location of a strip-shaped discharge-section on behalf of the uninterruptedly discharge of the evaporated medium.

144. The tunnel-arrangement according to claim 143, wherein this transducer-arrangement thereby is located in a from the atmospheric outer-air separated enclosed strip-shaped transducer-compartment of the uppertunnelblock, and whereby the under-electrodeplate thereof is part of the lower wall of this block, with around the transducer-section thereof a membrane-section, thereby also the maintaining of a pulsating-action of this transducer.

145. The tunnel-arrangement according to claim 143, wherein by-means of this transducer the uninterruptedly taking place of an insertion-process of particles of this semiconductor substance in the semiconductor top-layer of these successive, uninterruptedly underneath displacing semiconductor substrate sections.

146. The tunnel-arrangement according to claim 143, wherein for this semiconductor substance the appliance of parts of a high boiling fluidic stitch-substance on behalf of after the taking place of evaporation of this fluidic support-medium by means of this transducer, with a discharge of the accomplished vapor through the following strip-shaped discharge section of this uppertunnelblock, in the following semiconductor processing-section of this tunnel the accomplishing of an anchorage of the applied, typically nanometer-high layer of the fluidic stitch-substance on the semiconductor top-layer of the successive semiconductor substrate-sections, displacing underneath.

147. The tunnel-arrangement according to claim 146, wherein at-least locally the appliance of fluidic support-medium and the combination of a fluidic stitch-substance and nanometer-sized parts of a semiconductor substance in a solid form thereof on behalf of by means of a strip-shaped transducer-arrangement in this uppertunnelblock the also uninterruptedly taking place of an anchorage-process of this combination with the top-layer of the successive, uninterruptedly underneath displacing semiconductor substrate-sections.

148. The tunnel-arrangement according to claim 147, wherein at the end-section of such transducer-arrangement the also therewith establishing of a mechanically contact-free condition of such a therewith acquired semiconductor layer, with thereby at-least the above located uppertunnelblock-section extending in longitudinal direction.

149. The tunnel-arrangement according to 143, wherein by means of such transducer in the underneath thereof located uppersplitsection near the begin-section thereof by means of the vibrations thereof the also uninterruptedly taking place of a flatness-process of such uninterruptedly supplied combination of a semiconductor substance.

150. The tunnel-arrangement according to claim 143, wherein in a strip-shaped section of the uppertunnelblock at the therein located transducer-arrangement in the upper wall-section of the lowertunnelblock at-least also locally underneath thereof the location in the length-direction of the tunnel-passage of a number of combinations of in transverse direction extending strip-shaped supply-grooves, with the connection thereupon of typically a number of supply-channels in this block for typically a number of discharge-channels for this-transfer-medium, with a large number of aside each other located medium transmit-grooves in-between.

151. The tunnel-arrangement according to claim 137, wherein at membrane-section of this transducer-arrangement at its end-section a maximum height of the uppersplit-section, located underneath, on behalf of an optimal discharge of the established vapor of the fluidic support-medium and the accomplishing of a typically (sub) micrometer-high layer of these particles of a semiconductor substance in a solid or fluidic form thereof.

152. The tunnel-arrangement according to claim 137, wherein the possible appliance of several of the semiconductor appliances and means of the semiconductor installation, -tunnel-arrangements and -devices, as shown and described in the by the applicator filed additional PCT Patent-Applications.

153. A method for transfer and processing of successive substrate-sections, using a semiconductor substrate transfer/processing tunnel-arrangement, comprising:
the insertion of at-least one strip-shaped supply-device, mainly extending in a transverse direction, and in at-least the uppertunnelblock thereof during its operation the taking place of an uninterrupted supply of the combination of a typically low-boiling fluidic support-medium and particles of a semiconductor substance in a solid- or fluidic form thereof toward the micrometer-high strip-shaped upper split section above the successive, uninterruptedly underneath displacing semiconductor substrate-sections.

154. A method according to claim 153, wherein such uninterruptedly displacement of these successive semiconductor substrate-sections is accomplished by means of at-least also during its operation uninterrupted band or folio as an at-least temporary semiconductor underlayer thereof.

155. A method according to claim 154, wherein underneath a strip-shaped section of the uppertunnelblock, with therein the location of a transducer-arrangement and in the upper wall-section of the lowertunnelblock at-least also locally underneath thereof the location in the length-direction of the tunnel-passage of a number of combinations of in transverse direction extending strip-shaped supply-grooves, with the connection thereupon of typically a number of supply-channels in this block for typically gaseous or fluidic transfer-medium, and thereupon following discharge-grooves, with also typically a number of discharge channels for this transfer-medium, with a large number of aside each other located medium transmit-grooves in-between, by means of such successive flows of transfer-folio or band through this tunnel-passage.

156. A method according to claim 155, wherein at the exit of the tunnel-arrangement the accomplishing of successive substrate-sections, from which in a device beyond this tunnel-arrangement by means of dividing these successive substrate-sections the accomplishing of semiconductor chips.
